(19) United States
(12) Patent Application Publication
(10) Pub. No.: US 2026/0247496 A1
(43) Pub. Date: Aug. 20, 2026

(54) CERAMIC HEATER

(71) Applicant: NGK INSULATORS, LTD., Nagoya-shi (JP)

(72) Inventors: Kentaro KIMURA, Nagoya-shi (JP); Yutaka UNNO, Nagoya-shi (JP)

(73) Assignee: NGK INSULATORS, LTD., Nagoya-shi (JP)

(21) Appl. No.: 19/576,324

(22) Filed: Mar. 24, 2026

Related U.S. Application Data
(63) Continuation of application No. PCT/JP2025/033838, filed on Sep. 25, 2025.

(30) Foreign Application Priority Data
Feb. 20, 2025 (JP) 2025-026157

(51) Int. Cl. H05B 3/28; H10P 72/00; H10P 72/76

(52) U.S. Cl. CPC H05B 3/283; H10P 72/0432; H10P 72/7616

(57) ABSTRACT

The ceramic heater includes: a first heater layer; a plurality of first power feeding terminals; a second heater layer; a plurality of second power feeding terminals; a plurality of jumper layers. The jumper layers are connected to a corresponding second power feeding terminal, and are connected to the second heater layer via a corresponding connecting portion. In the jumper layers, a slit is formed which divides the jumper layer into regions including: a first region on an innermost side, including a first end portion to which the second power feeding terminal is connected; second region on an outermost side, including a second end portion to which the connecting portion is connected. The first region extends in a positive direction, and the region other than the first region extends in an opposite direction to a direction in which the region being adjacent thereto on the inner side extends.

### CROSS-REFERENCE TO RELATED APPLICATIONS

This application claims priority from Japanese Patent Application No. 2024-26157 filed on Feb. 20, 2025, the contents of which are incorporated herein by reference in their entirety.

### TECHNICAL FIELD

The present disclosure relates to a ceramic heater.

### BACKGROUND ART

In a semiconductor manufacturing apparatus, a ceramic heater is used to heat a wafer when, for example, such processing as film forming or etching is performed on the wafer. As the ceramic heater, there has been widely used a ceramic heater including a disc-shaped plate made of ceramic and a cylindrical shaft made of ceramic bonded to the plate. The plate includes a heater layer built therein. The heater layer is formed from a resistance heating element that generates heat through energization. In order to uniformly heat entirety of the wafer, the plate is required to have thermal uniformity with a small temperature difference over an area from a center to an outer periphery of the plate. Thus, there has been known a multi-zone ceramic heater including a plate that is divided into two heating zones: an inner zone on the center side and an outer zone on the outer periphery side. A heater layer is arranged for each of the heating zones. The multi-zone ceramic heater adjusts a heating temperature for each of the heating zones by individually controlling a current flowing through a first heater layer arranged in the inner zone and a current flowing through a second heater layer arranged in the outer zone.

In the multi-zone ceramic heater, power feeding terminals for feeding power to the second heater layer are generally built in the plate at positions in the vicinity of the center of the plate. Thus, a jumper layer that allows conduction between the power feeding terminals and the second heater layer is built in the plate at a position lower than the first heater layer. The jumper layer is formed from, for example, a thin strip-shaped conductive member extending linearly in a radial direction of the plate. In the ceramic heater including such a jumper layer built in the plate, however, heat is generated at a position at which the jumper layer is arranged due to heat generation caused by electrical resistance of the jumper layer. Thus, a localized hot spot or cool spot is formed in the plate. Accordingly, the thermal uniformity of the plate may be impaired.

Thus, in a ceramic heater described in Japanese Patent Application Laid-open No. 2018-5999, as illustrated in FIG. 13A, in order to improve the thermal uniformity of the plate, first lower heat generating resistance elements 103 are arranged over an entire area of an inner zone 101 in which an upper heat generating resistor corresponding to the first heater layer is arranged when viewed in a thickness direction of a plate 100. The first lower heat generating resistance elements 103 correspond to a jumper layer that allows conduction between power feeding terminals 106 and second lower heat generating resistance elements 104 corresponding to the second heater layer arranged in an outer zone 102.

### SUMMARY OF INVENTION

In the ceramic heater described in Japanese Patent Application Laid-open No. 2018-5999, however, as illustrated in FIG. 13B, when the first lower heat generating resistance elements 103 are energized, a current flows between the power feeding terminals 106 and connecting portions 105 between the first lower heat generating resistance elements 103 and the second lower heat generating resistance elements 104 through the shortest paths indicated by the arrows. Thus, the first lower heat generating resistance elements 103 do not uniformly generate heat over an entire area thereof. A localized hot spot or cool spot is formed in the plate 100 due to major heat generation occurring in part of the first lower heat generating resistance elements 103. Thus, thermal uniformity of the plate 100 may be impaired.

The present disclosure has one object to provide a ceramic heater capable of improving thermal uniformity of a plate.

According to the present disclosure, there is provided a ceramic heater, including: a plate; a first heater layer; a plurality of first power feeding terminals; a second heater layer; a plurality of second power feeding terminals; a plurality of jumper layers. The plate includes a first principal surface configured to support a wafer, and a second principal surface positioned across a gap from the first principal surface in a thickness direction of the plate. The first heater layer is built in the plate, and is formed from a resistance heating element configured to generate heat through energization. The plurality of first power feeding terminals are built in the plate so as to be arranged in a central portion of the plate when viewed in the thickness direction of the plate, and are connected to the first heater layer. The second heater layer having a ring shape is built in the plate so as to be arranged on an outer side of the first heater layer when viewed in the thickness direction of the plate, and is formed from a resistance heating element configured to generate heat through energization. The plurality of second power feeding terminals are built in the plate so as to be arranged in the central portion of the plate when viewed in the thickness direction of the plate, and are configured to feed power to the second heater layer. The plurality of jumper layers are built in the plate so as to be arranged on the second principal surface side with respect to the first heater layer in the thickness direction of the plate and arranged on an inner side of the second heater layer when viewed in the thickness direction of the plate. In the ceramic heater according to the present disclosure, each of the plurality of jumper layers is connected to a corresponding one of the plurality of second power feeding terminals, and is connected to the second heater layer through intermediation of a corresponding one of a plurality of connecting portions provided to the second heater layer. Further, the plurality of jumper layers each have at least one slit which divides the jumper layer into a plurality of regions, the plurality of regions including at least: a first region being an innermost region including a first end portion to which a corresponding one of the second power feeding terminals is connected; and a second region being an outermost region including a second end portion to which a corresponding one of the connecting portions is connected, when viewed in the thickness direction of the plate, the plurality of regions being continuous so that the first region extends in a positive circumferential direction of the plate and the region other than the first region extends in an opposite circumferential direction of the plate to a direction in which the region being adjacent on an inner side extends. Further, widths of the plurality of regions are larger than a width of the resistance heating element which forms the second heater layer.

With the ceramic heater according to the present disclosure, thermal uniformity of the plate can be improved.

### BRIEF DESCRIPTION OF DRAWINGS

FIG. 1 is a sectional view for illustrating a schematic structure of a ceramic heater according to one embodiment of the present disclosure.

FIG. 2 is a perspective view of a first heater layer, a second heater layer, and jumper layers.

FIG. 3 is a plan view of the first heater layer, the second heater layer, and the jumper layers.

FIG. 4 is a plan view of the second heater layer and the jumper layers.

FIG. 5 is a plan view of the second heater layer.

FIG. 6 is a plan view of the jumper layers.

FIG. 7 is a view for conceptually illustrating an example in which a wiring pattern of a second resistance heating element is a parallel circuit when two jumper layers are provided.

FIG. 8 is a view for conceptually illustrating an example in which the wiring pattern of the second resistance heating element is a series circuit when two jumper layers are provided.

FIG. 9 is a plan view of the jumper layers of a modification example.

FIG. 10A is a sectional view for illustrating a schematic structure of a joint portion between a connecting portion and the jumper layer.

FIG. 10B is a sectional view for illustrating a schematic structure of a modification example of the joint portion between the connecting portion and the jumper layer.

FIG. 11 is a sectional view of the ceramic heater according to a modification example of the present disclosure.

FIG. 12A and FIG. 12B are plan views of the jumper layers of the modification example.

FIG. 13A and FIG. 13B are sectional views of a ceramic heater of a related-art example.

### DESCRIPTION OF EMBODIMENTS

### Outline of Embodiments

First, aspects of carrying out a ceramic heater according to the present disclosure are listed and described.

A ceramic heater according to a first aspect of the present disclosure includes: a plate; a first heater layer; a plurality of first power feeding terminals; a second heater layer; a plurality of second power feeding terminals; a plurality of jumper layers. The plate includes a first principal surface that supports a wafer, and a second principal surface positioned across a gap from the first principal surface in a thickness direction of the plate. The first heater layer is built in the plate, and is formed from a resistance heating element that generates heat through energization. The plurality of first power feeding terminals are built in the plate so as to be arranged in a central portion of the plate when viewed in the thickness direction of the plate, and are connected to the first heater layer. The second heater layer having a ring shape is built in the plate so as to be arranged on an outer side of the first heater layer when viewed in the thickness direction of the plate, and is formed from a resistance heating element that generates heat through energization. The plurality of second power feeding terminals are built in the plate so as to be arranged in the central portion of the plate when viewed in the thickness direction of the plate, and feeds power to the second heater layer. The plurality of jumper layers are built in the plate so as to be arranged on the second principal surface side with respect to the first heater layer in the thickness direction of the plate and arranged on an inner side of the second heater layer when viewed in the thickness direction of the plate. In the ceramic heater according to the first aspect, each of the plurality of jumper layers is connected to a corresponding one of the plurality of second power feeding terminals, and is connected to the second heater layer through intermediation of a corresponding one of a plurality of connecting portions provided to the second heater layer. Further, the plurality of jumper layers each have at least one slit which divides the jumper layer into a plurality of regions, the plurality of regions including at least: a first region being an innermost region including a first end portion to which a corresponding one of the second power feeding terminals is connected; and a second region being an outermost region including a second end portion to which a corresponding one of the connecting portions is connected, when viewed in the thickness direction of the plate, the plurality of regions being continuous so that the first region extends in a positive circumferential direction of the plate and the region other than the first region extends in an opposite circumferential direction of the plate to a direction in which the region being adjacent on an inner side extends. Further, widths of the plurality of regions are larger than a width of the resistance heating element which forms the second heater layer.

The plurality of jumper layers are each configured so that, when viewed in the thickness direction of the plate, the plurality of regions including at least: the first region on the innermost side, including the first end portion to which a corresponding one of the second power feeding terminals is connected; and the second region on the outermost side, including the second end portion to which a corresponding one of the connecting portions is connected, are continuous in a zigzag pattern. Thus, in the plurality of jumper layers, when the second heater layer is energized to achieve conduction between the second heater layer and the second power feeding terminals, a current spreads in a wide area of the jumper layers. Thus, the jumper layers generate heat uniformly in their entire or substantially entire areas. As a result, formation of a localized hot spot or cool spot in the plate due to the heat generation of the jumper layers themselves can be suppressed. In addition, when the widths of the regions of each of the jumper layers are large and thus areas of the regions are large, resistance in each of the regions of the jumper layer is reduced. As a result, the amount of heat generated in the jumper layers when the second heater layer is energized can be reduced. Thus, with the ceramic heater according to the first aspect, thermal uniformity of the plate can be improved.

As a ceramic heater according to a second aspect of the present disclosure, the ceramic heater according to the above-mentioned first aspect may be configured such that the widths of the plurality of regions are each 2 times or more and 75 times or less the width of the resistance heating element which forms the second heater layer.

With the ceramic heater according to the second aspect, the resistance in each of the regions of the jumper layer can be suitably reduced, and accordingly the amount of heat generated in the jumper layers when the second heater layer is energized can be suitably reduced. Thus, the thermal uniformity of the plate can be further improved.

As a ceramic heater according to a third aspect of the present disclosure, the ceramic heater according to the above-mentioned first aspect or second aspect may be configured such that a width of the slit is 1.0 mm or more.

With the ceramic heater according to the third aspect, the amount of heat generated in the jumper layers when the second heater layer is energized can be suitably reduced by appropriately setting a distance between the regions of the jumper layer across the slit. Thus, the thermal uniformity of the plate can be further improved.

As a ceramic heater according to a fourth aspect of the present disclosure, the ceramic heater according to any one of the above-mentioned first aspect to third aspect may be configured such that the one slit is formed in each of the plurality of jumper layers, the slit dividing the jumper layer into, when viewed in the thickness direction of the plate, two regions including: the first region extending in the positive circumferential direction of the plate from the first end portion; and the second region extending to the second end portion in a negative circumferential direction of the plate being opposite to the positive circumferential direction.

With the ceramic heater according to the fourth aspect, the widths of the regions of each of the jumper layers can be set large. As a result, the areas of the regions of the jumper layer can be increased to suitably reduce the resistance in each of the regions. Thus, the amount of heat generated in the jumper layers when the second heater layer is energized can be suitably reduced, and hence the thermal uniformity of the plate can be further improved.

As a ceramic heater according to a fifth aspect of the present disclosure, the ceramic heater according to any one of the above-mentioned first aspect to fourth aspect may be configured such that each of the plurality of connecting portions of the second heater layer protrudes inward toward a corresponding one of the plurality of jumper layers to be connected to the corresponding jumper layer.

With the ceramic heater according to the fifth aspect, the second heater layer and each of the jumper layers can be connected to each other with a simple structure.

As a ceramic heater according to a sixth aspect of the present disclosure, the ceramic heater according to the above-mentioned fifth aspect may be configured such that a thickness of a joint portion at which the connecting portion and the jumper layer are connected is larger than a thickness of each of the jumper layers and a thickness of the second heater layer.

The joint portion at which the connecting portion of the second heater layer and the jumper layer are connected is liable to generate heat because a current concentrates at the joint portion when the second heater layer is energized. With the ceramic heater according to the sixth aspect, however, resistance at the joint portion is reduced because of a large thickness of the joint portion. As a result, the amount of heat generated at the joint portion when the second heater layer is energized can be reduced. Thus, the formation of a localized hot spot in the plate can be suppressed, and hence the thermal uniformity of the plate can be further improved.

As a ceramic heater according to a seventh aspect of the present disclosure, the ceramic heater according to any one of the above-mentioned first aspect to sixth aspect may be configured such that a thickness of each of the jumper layers is larger than a thickness of the second heater layer.

With the ceramic heater according to the seventh aspect, with a larger thickness of the jumper layer than the thickness of the second heater layer, the resistance in the jumper layers is reduced. Accordingly, the amount of heat generated in the jumper layers when the second heater layer is energized can be suitably reduced. Thus, the thermal uniformity of the plate can be further improved.

As a ceramic heater according to an eighth aspect of the present disclosure, the ceramic heater according to any one of the above-mentioned first aspect to seventh aspect may be configured such that: the plurality of jumper layers are arranged inside the plate at positions with the same height in the thickness direction of the plate, and are arranged in a state of being separated from each other in the circumferential direction of the plate when viewed in the thickness direction of the plate; and when viewed in the thickness direction of the plate, an angle formed between a first line segment which connects a center of the plate and one end of the slit and a second line segment which connects the center of the plate and another end of the slit is ½×360°/n (where “n” represents the number of jumper layers) or more.

With the ceramic heater according to the eighth aspect, a current is enabled to spread in a wider area of the jumper layers. As a result, the thermal uniformity of the plate can be further improved.

As a ceramic heater according to a ninth aspect of the present disclosure, the ceramic heater according to any one of the above-mentioned first aspect to eighth aspect may be configured such that: when viewed in the thickness direction of the plate, the plate includes: an inner zone which is a circular region within a first distance from a center of the plate, and in which the first heater layer and the plurality of jumper layers are arranged; and an outer zone which is an annular region within a second distance from the center of the plate on an outer side of the inner zone, and in which the second heater layer is arranged; and a proportion of an area of the plurality of jumper layers to an area of the inner zone is 75% or more.

With the ceramic heater according to the ninth aspect, the jumper layers have a large area, and hence the resistance in the jumper layers is suitably reduced. Accordingly, the amount of heat generated in the jumper layers when the second heater layer is energized can be suitably reduced. Thus, the thermal uniformity of the plate can be further improved.

### Specific Examples of Embodiment

Next, a specific embodiment of the ceramic heater according to the present disclosure is described with reference to the drawings. Throughout the drawings, parts that are the same as, or correspond to, each other are denoted by the same reference numeral.

### <Ceramic Heater>

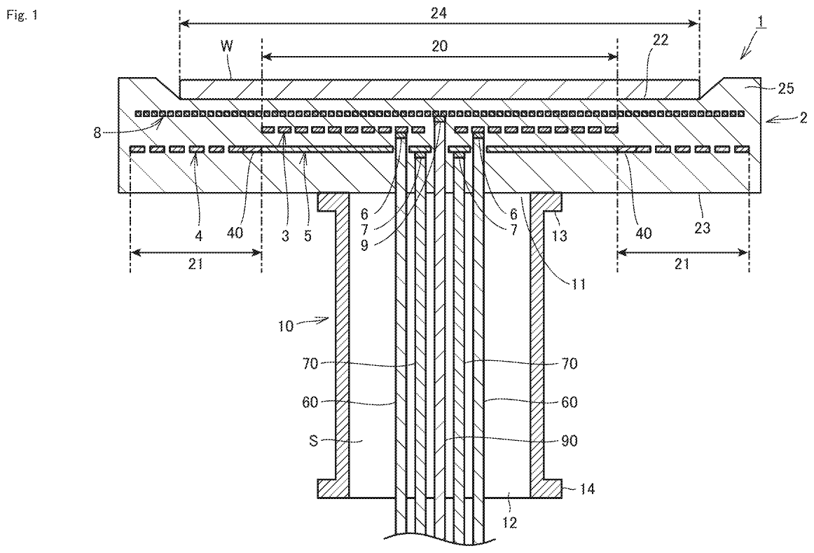

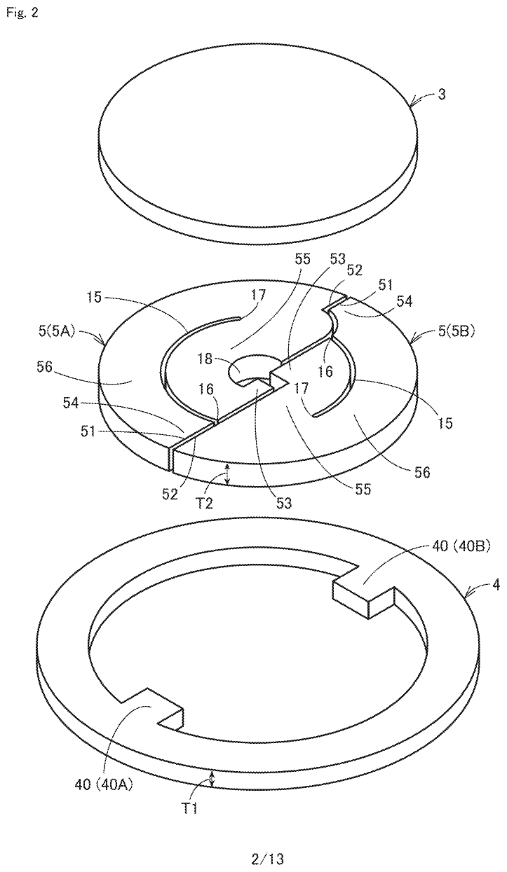

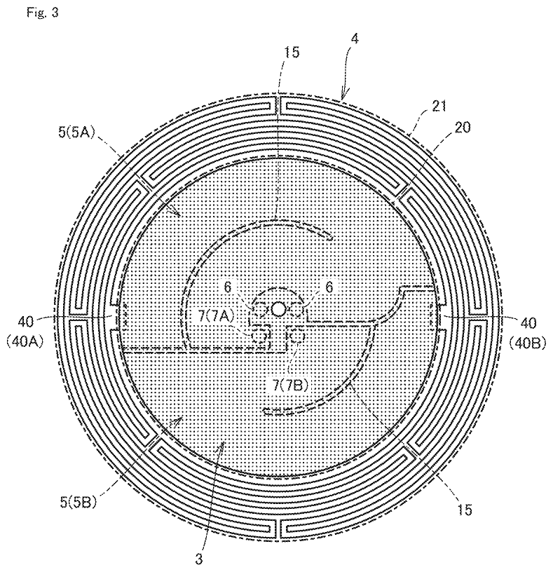

FIG. 1 is a sectional view for illustrating a schematic structure of a ceramic heater 1 according to one embodiment of the present disclosure. FIG. 2 is a perspective view of a first heater layer 3, a second heater layer 4, and a plurality of jumper layers 5, in which schematic structures are illustrated for the first heater layer 3 and the second heater layer 4. FIG. 3 is a plan view of the first heater layer 3, the second heater layer 4, and the plurality of jumper layers 5. In the following description, viewing an object in a thickness direction of a plate 2 is referred to as “plan view.” Further, a shape of the object as viewed along the thickness direction of the plate 2 is referred to as “shape in plan view.”

The ceramic heater 1 is installed in a vacuum chamber of a semiconductor manufacturing apparatus as a stage made of ceramic for supporting a wafer W. An interior of the vacuum chamber is set to a vacuum atmosphere or a reduced-pressure atmosphere. For example, film forming processing in which a thin film is formed on the wafer W by chemical vapor deposition (CVD) or processing of etching the wafer W is executed inside the vacuum chamber. The ceramic heater 1 is used to heat the wafer W so that a temperature of the wafer W is set to a desired temperature when, for example, the film forming processing and the etching processing are performed on the wafer W in the semiconductor manufacturing apparatus.

The ceramic heater 1 includes: the plate 2 made of ceramic with a sheet-like shape; a shaft 10 made of ceramic with a tubular shape; and the first heater layer 3, the second heater layer 4, the plurality of jumper layers 5, a plurality of first power feeding terminals 6, and a plurality of second power feeding terminals 7, which are built in the plate 2.

Inside the plate 2, for example, the second heater layer 4 is arranged closer to a second principal surface 23 (on the second principal surface 23 side) than the first heater layer 3, and the plurality of jumper layers 5 are arranged at positions with the same height as that of the second heater layer 4. The phrase “position with the same height” includes a position that is exactly the same in height, and a position that is substantially the same in height in the thickness direction of the plate 2.

When viewed in the thickness direction of the plate 2, the plate 2 includes: an inner zone 20 being a region within a first distance from a center of the plate 2; and an outer zone 21 being a ring-shaped region within a second distance (>the first distance) from the center of the plate 2 and on an outer side of the inner zone 20. In this case, the term “outer side” when the plate 2 is viewed in the thickness direction refers to an outer peripheral edge side of the plate 2, and the term “inner side” when the plate 2 is viewed in the thickness direction refers to the center side of the plate 2.

The inner zone 20 is a region having an outer peripheral edge with a similar shape to a shape of an outer peripheral edge of the plate 2 in plan view. In the inner zone 20, the first heater layer 3 is arranged so as to extend over an entire or substantially entire area thereof. Further, in the inner zone 20, the plurality of jumper layers 5 are arranged so as to extend over the entire or substantially entire area at a position with a height different from that of the first heater layer 3 in the thickness direction of the plate 2. The phrase “the first heater layer 3 or the plurality of jumper layers 5 extending over the entire or substantially entire area of the inner zone 20” means that an area of the first heater layer 3 or an area of the plurality of jumper layers 5 occupies all or a major part of an area of a region extending from the center of the plate 2 to the outer peripheral edge of the inner zone 20 in plan view.

The outer zone 21 is a ring-shaped region having an outer peripheral edge with a similar shape to that of the outer peripheral edge of the plate 2 in plan view. In the outer zone 21 having a ring shape, the second heater layer 4 having a ring shape is arranged so as to extend over an entire or substantially entire area thereof. The phrase “second heater layer 4 extending over the entire or substantially entire area of the outer zone 21” means that an area of the second heater layer 4 occupies all or a major part of an area of a region extending from the outer peripheral edge of the inner zone 20 to the outer peripheral edge of the outer zone 21 in plan view.

The plurality of first power feeding terminals 6 are terminals for feeding power to the first heater layer 3. In this embodiment, two first power feeding terminals 6 are built in the plate 2. The plurality of first power feeding terminals 6 are built in a region of the plate 2 in the vicinity of the center of the plate 2 in plan view, and are electrically connected to the first heater layer 3. First power feeding members 60 made of metal, each having, for example, a rod-like shape, are electrically connected to the plurality of first power feeding terminals 6. A current is caused to flow through the first heater layer 3 from an external heater power source via the first power feeding members 60 and the first power feeding terminals 6. In the present disclosure, the region of the plate 2 in the vicinity of the center in plan view is referred to as “central portion of the plate 2.”

The plurality of second power feeding terminals 7 are terminals for feeding power to the second heater layer 4. In this embodiment, two second power feeding terminals 7 are built in the plate 2. The plurality of second power feeding terminals 7 are built in the plate 2 at the central portion of the plate 2 in plan view, and are each electrically connected to a corresponding one of the plurality of jumper layers 5. When the plurality of jumper layers 5 are electrically connected to the second heater layer 4, conduction between the plurality of second power feeding terminals 7 and the second heater layer 4 is enabled. Second power feeding members 70 made of metal, each having, for example, a rod-like shape, are electrically connected to the plurality of second power feeding terminals 7. A current is caused to flow through the second heater layer 4 from an external heater power source via the second power feeding members 70, the second power feeding terminals 7, and the jumper layers 5.

In the ceramic heater 1, electrodes 8 which are at least one of radio-frequency electrodes (RF electrodes) or electrostatic chuck electrodes (ESC electrodes) or electrodes 8 functioning as any of the RF electrodes or the ESC electrodes may be further provided inside the plate 2. When a radio-frequency voltage is applied to the RF electrode, the RF electrode generates plasma between the RF electrode and an upper electrode installed on a ceiling inside the vacuum chamber. When a voltage is applied to the ESC electrode, the ESC electrode chucks the wafer W supported by the plate 2 through electroadhesion.

It is preferred that the electrodes 8 be arranged on a first principal surface 22 side with respect to the first heater layer 3 in the thickness direction of the plate 2. A third power feeding terminal 9 being a terminal for feeding power to the electrodes 8 is built in the plate 2 at the central portion of the plate 2 in plan view. A third power feeding member 90 made of metal having, for example, a rod-like shape is electrically connected to the third power feeding terminal 9. The electrodes 8 are energized from, for example, an external radio-frequency power source via the third power feeding member 90 and the third power feeding terminal 9.

The power feeding members 60, 70, and 90 are inserted from the second principal surface 23 into the plate 2 at the central portion of the plate 2 in plan view to be electrically connected to the corresponding power feeding terminals 6, 7, and 9, respectively.

### <Description of Plate>

Reference is made to FIG. 1. The plate 2 is a plate made of ceramic. The plate 2 contains, as a main component, for example, aluminum nitride (AlN), aluminum oxide (Al₂O₃), silicon carbide (SiC), or silicon nitride (Si₃N₄). The plate 2 is preferred to contain, as a main component, aluminum nitride high in thermal conductivity. The term “main component” means a component having the highest content among contained components, and the content of the main component is, for example, 50% or higher by mass, preferably 70% or higher by mass, and more preferably 90% or higher by mass. The plate 2 may contain other components such as a component originating from a sintering aid, as long as the above-mentioned material is contained as the main component. A rare-earth metal oxide is given as an example of the sintering aid. The plate 2 is formed from, for example, a sintered ceramic body obtained by baking ceramic powder, but may be formed by other methods, for example, may be formed from a laminate obtained by kneading a mixture of ceramic powder and a binder into a sheet form, layering a plurality of thus obtained green sheets, and firing the layered green sheets.

The plate 2 includes a first principal surface 22 and a second principal surface 23 which are a pair of principal surfaces positioned across a gap from each other in the thickness direction. The first principal surface 22 and the second principal surface 23 are parallel, or substantially parallel, to each other. The phrase “substantially parallel” includes a case in which one is tilted with respect to the other to a certain degree within tolerance, a case in which at least one is somewhat warped and is not flat, and the like. In the present disclosure, the first principal surface 22 side is defined as an upper side, and the second principal surface 23 side is defined as a lower side, in the thickness direction of the plate 2.

The shape of the plate 2 in plan view is a circular shape in this embodiment, but the shape is not limited to a circular shape. The circular shape is not always required to be a complete circle, and may be an incomplete circle missing a part, such as orientation flat. A diameter of the plate 2 may be appropriately determined in accordance with a diameter of the wafer W supported by the plate 2. The diameter of the plate 2 is, for example, 200 mm or more and 400 mm or less. A thickness of the plate 2 is, for example, 5 mm or more and 30 mm or less.

The first principal surface 22 of the plate 2 includes a wafer supporting region 24 for supporting the wafer W. An entire area of the first principal surface 22 may be the wafer supporting region 24. As in this embodiment, however, an outer peripheral wall 25 rising over the entire circumference of the plate 2 in its circumferential direction may be formed on a region of the first principal surface 22, the region extending inward from an outer peripheral edge of the first principal surface 22 and having a predetermined width. When the outer peripheral wall 25 to surround a wafer is formed around the wafer supporting region 24, positioning of the wafer W is facilitated.

For example, an annular protrusion called a seal band may be formed on the wafer supporting region 24 of the first principal surface 22 so that the wafer W is placed on the annular protrusion. In this manner, a space surrounded by the annular protrusion can be defined between the wafer W and the plate 2. Supplying a gas with high thermal conductivity, for example, a helium gas enables efficient thermal conduction between the wafer W and the plate 2.

For example, a plurality of columnar or truncated conical small protrusions may be provided in the wafer supporting region 24 of the first principal surface 22. For example, the plurality of small protrusions can be provided in a region of the wafer supporting region 24 that is surrounded by the annular protrusion at intervals equal to one another. A height of each of the small protrusions is the same, or substantially the same, as the height of the annular protrusion. Placing the wafer W not only on the annular protrusion but also on the plurality of small protrusions enables entirety of the wafer W to be supported evenly.

Various holes extending in the thickness direction of the plate 2 may be formed in the plate 2. For example, a hole for inserting a lift pin which is used to lift up the wafer W from the plate 2 after film forming processing or other processing on the wafer W is finished is formed in the plate 2. Further, a hole for supplying gas into the space surrounded by the annular protrusion between the wafer W and the plate 2 is formed in the plate 2. Further, a hole for inserting a thermocouple that measures a temperature of the plate 2 is formed in the plate 2.

Reference is made to FIG. 3. In this embodiment, the inner zone 20 is a circular region, and the outer zone 21 is an annular region arranged concentrically with the inner zone 20, in accordance with a shape of the plate 2 in plan view. A diameter of the inner zone 20 is, for example, 0.25 times or more and 0.75 times or less the diameter of the plate 2. An outer diameter of the outer zone 21 is larger than the diameter of the inner zone 20, and is, for example, 1.0 times or less the diameter of the plate 2.

### (Description of First Heater Layer)

Reference is made to FIG. 1 to FIG. 3. The first heater layer 3 spreads in a planar pattern inside the plate 2, along an imaginary plane parallel or substantially parallel to the first principal surface 22. The first heater layer 3 has, for example, a circular or substantially circular shape in plan view, and is arranged concentrically with the plate 2. The first heater layer 3 is arranged in the inner zone 20 in plan view, and an outer peripheral edge of the first heater layer 3 matches or substantially matches an outer peripheral edge of the inner zone 20.

The first heater layer 3 is formed from a resistance heating element containing, as a main component, a conductive material such as a high melting point metal, an alloy of a high melting point metal, or a carbide of a high melting point metal (hereinafter referred to as “first resistance heating element”). Molybdenum (Mo), tungsten (W), and niobium (Nb) are given as examples of the high melting point metal.

The first resistance heating element is formed from, for example, a thin plate having a shape in plan view corresponding to a shape of the inner zone 20 in plan view, or a thin plate with many small through-holes opened therein such as a perforated plate, a mesh, or a film formed by printing conductive paste. Alternatively, the first resistance heating element is formed from conductive paste, a coil, or a meandering element wire which is provided in a predetermined pattern with a single continuous line for a wiring over an entire or substantially entire area of the inner zone 20. It is preferred that the first resistance heating element be formed by printing conductive paste in a predetermined pattern for a wiring. In this case, the first power feeding terminals 6 are electrically connected to both ends of the wiring pattern of the first resistance heating element.

### (Description of Second Heater Layer)

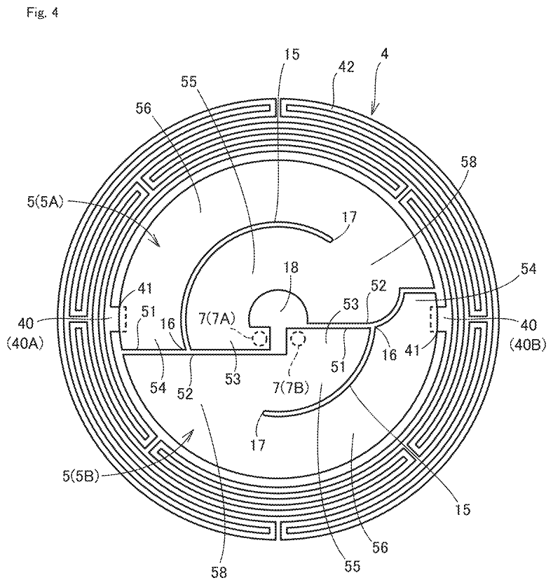

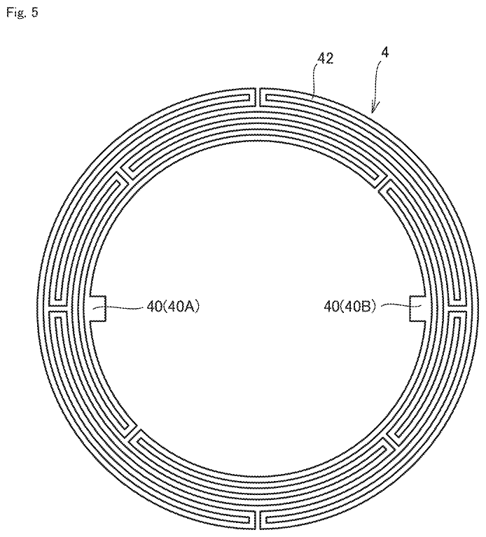

Reference is made to FIG. 1 to FIG. 5. The second heater layer 4 spreads in a planar pattern inside the plate 2, along an imaginary plane parallel or substantially parallel to the first principal surface 22. The second heater layer 4 is arranged below the first heater layer 3 in the thickness direction of the plate 2, but may be arranged above the first heater layer 3. It is preferred that the second heater layer 4 be arranged below the first heater layer 3.

The second heater layer 4 has, for example, an annular or substantially annular shape in plan view, and is arranged concentrically with the plate 2 on an outer side of the outer peripheral edge of the first heater layer 3 in plan view. The second heater layer 4 is arranged in the outer zone 21 in plan view, and an outer peripheral edge of the second heater layer 4 matches or substantially matches the outer peripheral edge of the outer zone 21. An inner peripheral edge of the outer zone 21 matches the outer peripheral edge of the inner zone 20.

The second heater layer 4 is formed from a resistance heating element 42 containing, as a main component, a conductive material such as a high melting point metal, an alloy of a high melting point metal, or a carbide of a high melting point metal (hereinafter referred to as “second resistance heating element 42”). Molybdenum (Mo), tungsten (W), and niobium (Nb) are given as examples of the high melting point metal.

The second resistance heating element 42 is formed from, for example, a thin plate having a shape in plan view corresponding to a shape of the outer zone 21 in plan view, or a thin plate with many small through-holes opened therein such as a perforated plate, a mesh, or a film formed by printing conductive paste. Alternatively, the second resistance heating element 42 is formed from conductive paste, a coil, or a meandering element wire which is provided in a predetermined pattern with a single continuous line for a wiring over an entire or substantially entire area of the outer zone 21. It is preferred that, as in this embodiment, the second resistance heating element 42 be formed by printing conductive paste in a predetermined pattern for a wiring.

A plurality of connecting portions 40 are formed integrally with the second heater layer 4 at an inner peripheral edge of the second heater layer 4. The number of connecting portions 40 matches the number of jumper layers 5. In this embodiment, two connecting portions 40, that is, a first connecting portion 40A and a second connecting portion 40B, are formed integrally with the second heater layer 4. The first connecting portion 40A and the second connecting portion 40B are formed at, for example, a pair of positions opposed to each other on the inner peripheral edge of the second heater layer 4, respectively. The positions at which the first connecting portion 40A and the second connecting portion 40B are arranged are not limited to positions opposed to each other, and may be appropriately set to preferred positions.

The plurality of connecting portions 40 are formed from a resistance heating element formed of the same conductive material as that for the second heater layer 4, and are each formed from, for example, a film formed by printing conductive paste. The plurality of connecting portions 40 protrude inward, that is, toward the center of the plate 2, from the inner peripheral edge of the second heater layer 4. The plurality of connecting portions 40 electrically connect the second heater layer 4 and the jumper layers 5 to each other.

When the second resistance heating element 42 which forms the second heater layer 4 is printing paste provided in a predetermined pattern for a wiring, a printing pattern of the second resistance heating element 42 may be a parallel circuit, or may be a series circuit.

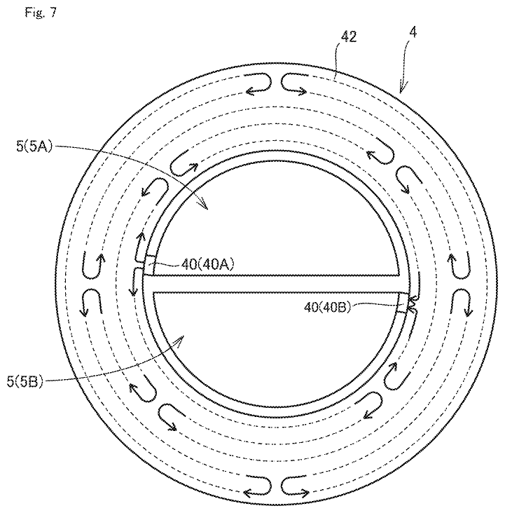

FIG. 7 conceptually shows an example in which the wiring pattern of the second resistance heating element 42 is a parallel circuit when the number of jumper layers 5 is two. In FIG. 7, the arrows represent directions of a current. In the example illustrated in FIG. 7, the wiring pattern of the second resistance heating element 42 which forms the second heater layer 4 extends in two directions from the first connecting portion 40A with the first jumper layer 5A corresponding to one of the two jumper layers 5. The wiring pattern then extends in a single continuous line in each of the two directions and reaches the second connecting portion 40B with the second jumper layer 5B corresponding to another one of the jumper layers. When the wiring pattern of the second resistance heating element 42 which forms the second heater layer 4 is a parallel circuit, the first connecting portion 40A and the second connecting portion 40B are formed at, for example, a pair of positions opposed to each other on the inner peripheral edge of the second heater layer 4.

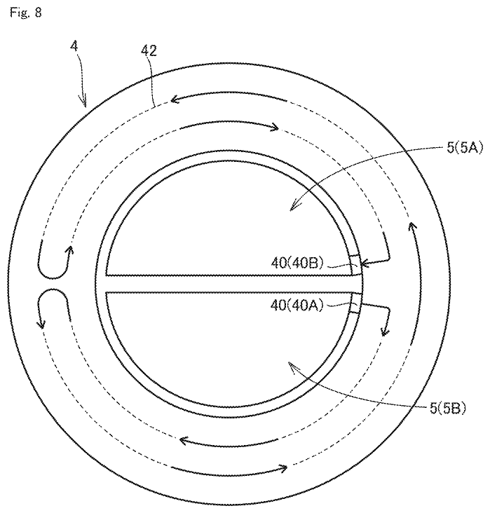

FIG. 8 conceptually shows an example in which the wiring pattern of the second resistance heating element 42 is a series circuit when the number of jumper layers 5 is two. In FIG. 8, the arrows represent directions of a current. In the example illustrated in FIG. 8, the wiring pattern of the second resistance heating element 42 which forms the second heater layer 4 extends in one direction from the first connecting portion 40A with the first jumper layer 5A. The wiring pattern then extends in a single continuous line and reaches the second connecting portion 40B with the second jumper layer 5B. When the wiring pattern of the second resistance heating element 42 which forms the second heater layer 4 is a series circuit, the first connecting portion 40A and the second connecting portion 40B are formed at, for example, positions adjacent to each other on the inner peripheral edge of the second heater layer 4.

In this embodiment, the wiring pattern of the second resistance heating element 42 in the second heater layer 4 is a parallel circuit. In terms of thermal uniformity of the plate 2, a series circuit and a parallel circuit can achieve equivalent thermal uniformity. In terms of prevention of an increase in resistance value, it is preferred that the wiring pattern be a parallel circuit.

### (Description of Jumper Layer)

Reference is made to FIG. 1 to FIG. 4 and FIG. 6. The plurality of jumper layers 5 spread in a planar pattern inside the plate 2, along an imaginary plane parallel or substantially parallel to the first principal surface 22. The plurality of jumper layers 5 are arranged below the first heater layer 3 and at a position with the same height as the height of the second heater layer 4 in the thickness direction of the plate 2. The phrase “position with the same height” includes a position that is exactly the same in height and a position that is substantially the same in height. The plurality of jumper layers 5 are arranged in the inner zone 20 in plan view. An outer peripheral edge of the plurality of jumper layers 5 may match the outer peripheral edge of the inner zone 20, or may be positioned inside or outside the outer peripheral edge of the inner zone 20.

The plurality of jumper layers 5 are each formed from a resistance heating element containing, as a main component, a conductive material such as a high melting point metal, an alloy of a high melting point metal, or a carbide of a high melting point metal (hereinafter referred to as “third resistance heating element”). Molybdenum (Mo), tungsten (W), and niobium (Nb) are given as examples of the high melting point metal.

The third resistance heating elements are formed from, for example, thin plates having a shape in plan view corresponding to the shape of the inner zone 20 in plan view when being all combined, thin plates, each with many small through-holes opened therein, such as perforated plates, meshes, or films formed by printing conductive paste. It is preferred that the third resistance heating elements be each formed by printing conductive paste in a predetermined shape.

The plurality of jumper layers 5 are arranged across a gap from each other in the circumferential direction of the plate 2 in plan view, and are arranged in a non-contact state in which the jumper layers 5 are spaced apart from each other. The number of jumper layers 5 matches the number of second power feeding terminals 7. In this embodiment, two jumper layers 5, that is, the first jumper layer 5A and the second jumper layer 5B are arranged in a non-contact state in which the jumper layers 5 are spaced apart from each other.

When the number of jumper layers 5 is two, a shape of each of two jumper layers 5, that is, the first jumper layer 5A and the second jumper layer 5B, in plan view is a semi-circular or substantially semi-circular shape. For example, a through-hole 18 that allows passage of the first power feeding members 60 and the third power feeding member 90 is formed in the first jumper layer 5A. The number of jumper layers 5 is not limited to two, and may be three or more, or four or more so as to match the number of second power feeding terminals 7. When the number of jumper layers 5 is four, a shape of each of the four jumper layers 5 in plan view is a quarter-circular or substantially quarter-circular shape.

The plurality of jumper layers 5 each have a first radial portion 51 substantially corresponding to a radius of the jumper layer 5 at the outer peripheral edge. A corresponding one of the plurality of connecting portions 40 of the second heater layer 4 is electrically connected to the jumper layer 5 in the vicinity of the first radial portion 51, and a corresponding one of the plurality of second power feeding terminals 7 is electrically connected to the jumper layer 5 in the vicinity of its center. More specifically, in this embodiment, the first connecting portion 40A of the second heater layer 4 is electrically connected to the first jumper layer 5A at the outer peripheral edge in the vicinity of the first radial portion 51, and one second power feeding terminal 7A is electrically connected to the first jumper layer 5A in the vicinity of the center. Further, the second connecting portion 40B of the second heater layer 4 is electrically connected to the second jumper layer 5B at the outer peripheral edge in the vicinity of the first radial portion 51, and another second power feeding terminal 7B is electrically connected to the second jumper layer 5B in the vicinity of the center.

The second power feeding terminals 7 for feeding power to the second heater layer 4 are arranged in the central portion of the plate 2 in plan view. Meanwhile, the second heater layer 4 is arranged in the outer zone 21 which is away from the second power feeding terminals 7 to the outer side. Thus, when conduction between the second heater layer 4 and the second power feeding terminals 7 is achieved through the jumper layers 5, the second heater layer 4 and the second power feeding terminals 7 are electrically connected to each other.

The plurality of jumper layers 5 each have at least one slit 15 formed therein. The slit 15 is an elongated hole that extends in the circumferential direction of the plate 2 in plan view, and passes through the jumper layer 5 in the thickness direction. In this embodiment, one slit 15 is formed in each of the jumper layers 5.

A shape of the slit 15 in plan view is, for example, an arc-like shape. The slit 15 extends in an arc-like manner from a start end 16 to a terminal end 17. The start end 16 is positioned on the outer side with respect to the second power feeding terminal 7 at the first radial portion 51 substantially corresponding to the radius of the jumper layer 5. The terminal end 17 of the slit 15 is located at a position away from a second radial portion 52. The second radial portion 52 substantially corresponds to the radius of the jumper layer 5, and is opposite to the first radial portion 51 at which the start end 16 is positioned. With this arrangement, the jumper layer 5 includes a first region 55 on an inner side of the slit 15. The first region 55 extends from a first end portion 53 to which a corresponding one of the second power feeding terminals 7 is connected, in a positive circumferential direction of the plate 2. Further, the jumper layer 5 includes a second region 56 on an outer side of the slit 15. The second region 56 extends to a second end portion 54 to which a corresponding one of the connecting portions 40 is connected, in a negative circumferential direction of the plate 2. Further, the jumper layer 5 includes a first turn-back region 58 turning back from the first region 55 toward the second region 56 between the second radial portion 52 and the terminal end 17 of the slit 15.

In the present disclosure, the term “positive circumferential direction” of the plate 2 refers to a direction for turning around the center of the plate 2 which is any of two rotational directions about the center of the plate 2, and the term “negative circumferential direction” of the plate 2 refers to a direction opposite to the positive circumferential direction. In this embodiment, the positive direction corresponds to a clockwise direction, and the negative direction corresponds to a counterclockwise direction.

Each of the plurality of jumper layers 5 has a single slit 15 formed therein. As a result, from the center of the plate 2 toward its outer peripheral edge in plan view, the first region 55 extending in the positive circumferential direction of the plate 2 and the second region 56 extending in the negative circumferential direction of the plate 2 are continuous with the presence of the first turn-back region 58 therebetween, forming a zigzag pattern that is bent alternately in the positive direction and the negative direction. With this configuration, for example, in the first jumper layer 5A, a current that has been transmitted from the second power feeding terminal 7A being one of the second power feeding terminals 7 to the first jumper layer 5A flows from the first end portion 53 through the first region 55, turns back through the first turn-back region 58, then flows through the second region 56 to the second end portion 54, and is transmitted to the second heater layer 4 via the first connecting portion 40A. In the second jumper layer 5B, the current that has been transmitted from the second heater layer 4 via the second connecting portion 40B to the second jumper layer 5B flows from the second end portion 54 through the second region 56, turns back through the first turn-back region 58, then flows through the first region 55 to the first end portion 53, and is transmitted to the second power feeding terminal 7B which is another one of the second power feeding terminals 7.

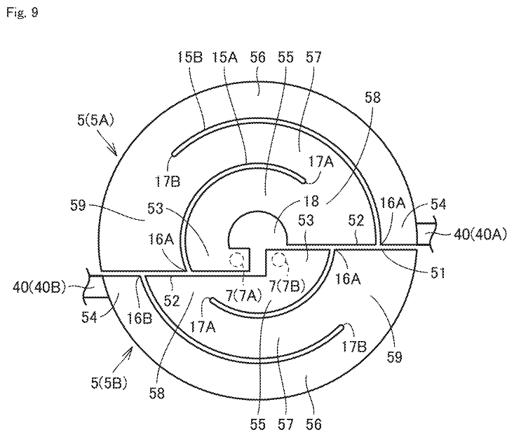

The number of slits 15 formed in the jumper layer 5 is not always limited to one, and two or more slits 15 may be formed therein. FIG. 9 shows an example in which two slits 15, that is, a first slit 15A and a second slit 15B, each having an arc-like shape in plan view, are formed in each of the two jumper layers 5 being the first jumper layer 5A and the second jumper layer 5B.

In the example illustrated in FIG. 9, the first slit 15A extends in an arc-like manner from a start end 16A to a terminal end 17A. The start end 16A is positioned at the first radial portion 51 on the outer side of the second power feeding terminal 7. The terminal end 17A of the first slit 15A is located at a position away from the second radial portion 52 of the jumper layer 5. The second slit 15B extends in an arc-like manner from a start end 16B to a terminal end 17B. The start end 16B is positioned at the second radial portion 52 of the jumper layer 5 on the outer side of the terminal end 17A of the first slit 15A. The terminal end 17B of the second slit 15B is located at a position away from the first radial portion 51 of the jumper layer 5. As a result, the jumper layer 5 includes the first region 55 on the inner side of the first slit 15A. The first region 55 extends in the positive circumferential direction of the plate 2 from the first end portion 53 to which a corresponding one of the second power feeding terminals 7 is connected. Further, the jumper layer 5 includes the second region 56 on the outer side of the second slit 15B. The second region 56 extends in the positive circumferential direction of the plate 2 to the second end portion 54 to which a corresponding one of the connecting portions 40 is connected. Further, the jumper layer 5 includes a third region 57 extending in the negative circumferential direction of the plate 2 between the first region 55 and the second region 56. Further, the jumper layer 5 includes the first turn-back region 58 between the second radial portion 52 and the terminal end 17A of the first slit 15A. The first turn-back region 58 turns back from the first region 55 toward the third region 57. Further, the jumper layer 5 includes a second turn-back region 59 between the first radial portion 51 and the terminal end 17B of the second slit 15B. The second turn-back region 59 turns back from the third region 57 toward the second region 56.

In each of the plurality of jumper layers 5, two slits 15A and 15B are formed to define, from the center toward the outer peripheral edge of the plate 2 in plan view: the first region 55 extending in the positive circumferential direction of the plate 2; the third region 57 extending in the negative circumferential direction of the plate 2; and the second region 56 extending in the positive circumferential direction of the plate 2. The first region 55, the third region 57, and the second region 56 are continuous with the presence of the first turn-back region 58 and the second turn-back region 59 therebetween to form a zigzag pattern that is bent alternately in the positive direction and the negative direction. As a result, for example, in the first jumper layer 5A, a current that has been transmitted from the second power feeding terminal 7A being one of the second power feeding terminals 7 to the first jumper layer 5A flows from the first end portion 53 through the first region 55, turns back through the first turn-back region 58, then flows through the third region 57, turns back through the second turn-back region 59, flows through the second region 56 to the second end portion 54, and is transmitted to the second heater layer 4 via the first connecting portion 40A. In the second jumper layer 5B, a current that has been transmitted from the second heater layer 4 via the second connecting portion 40B to the second jumper layer 5B flows from the second end portion 54 through the second region 56, turns back through the second turn-back region 59, then flows through the third region 57, turns back through the first turn-back region 58, flows through the first region 55 to the first end portion 53, and is transmitted to the second power feeding terminal 7B being another one of the second power feeding terminals 7.

As described above, in each of the plurality of jumper layers 5, the plurality of regions including at least the first region 55 on the innermost side and the second region 56 on the outermost side are formed so as to be continuous in a zigzag pattern in plan view. The first region 55 includes the first end portion 53 to which a corresponding one of the second power feeding terminals 7 is connected. The second region 56 includes the second end portion 54 to which a corresponding one of the connecting portions 40 is connected. Thus, in each of the plurality of jumper layers 5, when the second heater layer 4 is energized to allow conduction between the second heater layer 4 and the second power feeding terminal 7, a current spreads in a wide area of the jumper layer 5. The jumper layer 5 is formed from the resistance heating element. Thus, when the second heater layer 4 is energized, heat is generated in the jumper layer 5. In this embodiment, however, heat is generated uniformly in the entire or substantially entire area of the jumper layers 5. Thus, the formation of a localized hot spot or cool spot in the plate 2 due to the heat generation of the jumper layer 5 itself can be suppressed, and hence the thermal uniformity of the plate 2 can be improved.

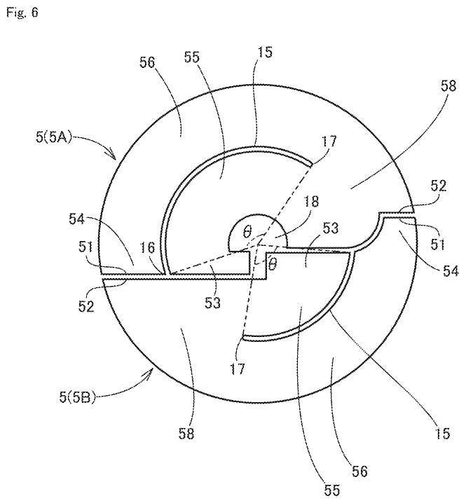

Reference is made to FIG. 6. A central angle θ of the slit 15 is not limited to a particular angle. When the number of jumper layers 5 arranged inside the plate 2 at the positions with the same height in the thickness direction is represented by “n”, the central angle θ is preferably ½×360°/n or more and ⅚×360°/n or less, more preferably ⅔×360°/n or more and ⅚×360°/n or less. The central angle θ of the slit 15 refers to an angle formed between a first line segment that connects the center of the plate 2 and the start end 16 being one end of the slit 15 and a second line segment that connects the center of the plate 2 and the terminal end 17 being another end (end opposite to the start end 16) of the slit 15 in plan view.

When the number of jumper layers 5 is two as in the example illustrated in FIG. 6, the central angle θ of the slit 15 is preferably 90° or more and 1500 or less, more preferably 1000 or more and 1500 or less, still more preferably 1000 or more and 1400 or less, even more preferably 1200 or more and 140° or less. When the number of jumper layers 5 is, for example, four, the central angle θ of the slit 15 is preferably 45° or more and 75° or less, more preferably 50° or more and 75° or less, still more preferably 50° or more and 70° or less, even more preferably 60° or more and 70° or less.

When the central angle θ of the slit 15 is set to ½×360°/n or more, a current can be spread in a wider area of the jumper layers 5. As a result, the thermal uniformity of the plate 2 can be further improved. Meanwhile, when the central angle θ of the slit 15 is set to ⅚×360°/n or less, widths of the turn-back regions 58 and 59 are reduced and thus localized heat generation in the plate 2 can be suppressed.

A width of the slit 15 is not limited to a particular width, but is preferably 1.0 mm or more and 3.0 mm or less, more preferably 1.5 mm or more and 2.5 mm or less. The width of the slit 15 refers to a length of part of the radius of the plate 2 from the center to the outer peripheral edge across the slit 15 in plan view. When the width of the slit 15 is set to 1.0 mm or more, insulation between two regions of the jumper layer 5 on the opposite sides of the slit 15 can be ensured. Meanwhile, when the width of the slit 15 is set to 3.0 mm or less, widths of the regions 55 to 57 of the jumper layer 5 can be increased to correspondingly increase areas of the regions 55 to 57. Thus, resistance in the regions 55 to 57 can be reduced.

The widths of the regions of the jumper layer 5, that is, the width of the first region 55 and the width of the second region 56 in the example illustrated in FIG. 6, the width of the first region 55, the width of the second region 56, and the width of the third region 57 in the example illustrated in FIG. 9 are larger than a width of the second resistance heating element 42 which forms the second heater layer 4. The widths of the plurality of regions 55 to 57 and the width of the second resistance heating element 42 each refer to a length of part of the radius of the plate 2 from the center to the outer peripheral edge across each of the regions 55 to 57 and the second resistance heating element 42 in plan view.

When the widths of the regions 55 to 57 of the jumper layer 5 are large, the areas thereof increase. Thus, resistance in the regions 55 to 57 of the jumper layer 5 is reduced. In this manner, the amount of power generated in the jumper layers 5 when the second heater layer 4 is energized can be reduced. Accordingly, the thermal uniformity of the plate 2 can be improved.

Meanwhile, when the widths of the regions 55 to 57 of the jumper layer 5 are set so as not to be excessively larger than the width of the second resistance heating element 42 which forms the second heater layer 4, a heat generation rate in the jumper layers 5 can be reduced. Thus, the thermal uniformity of the plate 2 can be improved.

Accordingly, the widths of the regions 55 to 57 of the jumper layer 5 are preferably 2 times or more and 75 times or less, more preferably 4 times or more and 15 times or less the width of the second resistance heating element 42 which forms the second heater layer 4.

As described above, in order to set the widths of the regions 55 to 57 of the jumper layer 5 to appropriate sizes, each of the plurality of jumper layers 5 has preferably one slit 15 or two slits 15, more preferably one slit 15.

The number of slits 15 formed in the plurality of jumper layers 5 is not required to be the same, and may be different for each of the jumper layers 5.

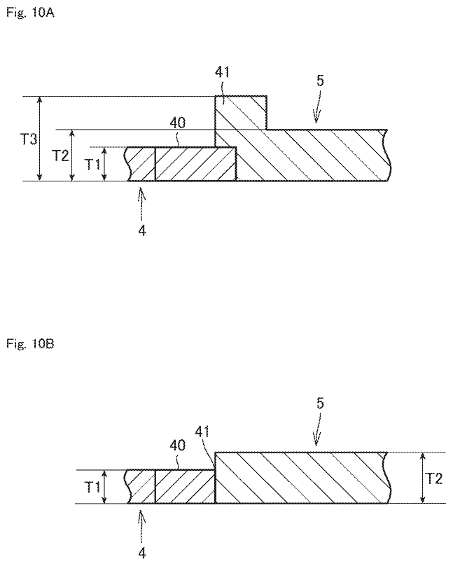

Reference is made to FIG. 2 and FIG. 10A. A thickness T2 of the jumper layer 5 is not limited to a particular thickness. However, it is preferred that the thickness T2 be larger than a thickness T1 of the second heater layer 4. The resistance of the jumper layer 5 can be suitably reduced by setting the thickness T2 of the jumper layer 5 larger than the thickness T1 of the second heater layer 4. As a result, the amount of heat generated in the jumper layers 5 when the second heater layer 4 is energized can be suitably reduced. Thus, the thermal uniformity of the plate 2 can be further improved.

Meanwhile, when the thickness T2 of the jumper layer 5 is excessively larger than the thickness T1 of the second heater layer 4, a large level difference is generated between the jumper layer 5 and the connecting portion 40 of the second heater layer 4. Stress is concentrated at the level difference portion when the ceramic heater 1 is manufactured or used, resulting in that damage may occur.

For the reason described above, the thickness T2 of the jumper layer 5 is preferably 1.2 times or more and 3.0 times or less, more preferably 1.3 times or more and 2.8 times or less, still more preferably 1.4 times or more and 2.5 times or less, even more preferably 1.5 times or more and 2.0 times or less the thickness T1 of the second heater layer 4.

Reference is made to FIG. 3. An area of the plurality of jumper layers 5 in plan view is not limited to a particular area. However, a proportion of the area of the plurality of jumper layers 5 to an area of the inner zone 20 is preferably 75% or more and 98% or less, more preferably 80% or more and 95% or less, still more preferably 90% or more and 95% or less. When the proportion of the area of the plurality of jumper layers 5 is 75% or more and thus the area of the jumper layers 5 is large, the resistance in the jumper layers 5 is suitably reduced. As a result, the amount of heat generated in the jumper layers 5 when the second heater layer 4 is energized can be suitably reduced. Thus, the thermal uniformity of the plate 2 can be suitably reduced.

Table 1 below shows the results of measurement of the thermal uniformity of the plate 2 for Test Examples 1 to 7 in which the proportion of the area of the plurality of jumper layers 5 to the area of the inner zone 20 is set to different percentage values. The thermal uniformity of the plate 2 is evaluated based on a difference between the highest temperature and the lowest temperature of the first principal surface 22 of the plate 2 which are obtained when a temperature of the first principal surface 22 is measured. A temperature measurement region of the first principal surface 22 includes entirety of the inner zone 20 and part of the outer zone 21 which is close to its boundary with the inner zone 20. According to Table 1, it is understood that the thermal uniformity of the plate 2 can be improved by setting the proportion of the area of the plurality of jumper layers 5 to 75% or more.

TABLE 1

| | Proportion of area of | Thermal uniformity |
|---|---|---|
| | jumper layers (%) | of plate (° C.) |
| Test Example 1 | 30 | 2.4 |
| Test Example 2 | 63 | 2.6 |
| Test Example 3 | 75 | 1.9 |
| Test Example 4 | 80 | 1.9 |
| Test Example 5 | 89 | 1.8 |
| Test Example 6 | 90 | 1.9 |
| Test Example 7 | 91 | 0.5 |

Reference is made to FIG. 10A. The connecting portion 40 of the second heater layer 4 may be connected to the jumper layer 5 in such a manner that the outer peripheral edge of the jumper layer 5 is overlaid on a distal end edge of the connecting portion 40. That is, a thickness T3 of a joint portion 41 at which the connecting portion 40 of the second heater layer 4 and the jumper layer 5 are connected is larger than the thickness T2 of the jumper layer 5 and the thickness T1 of the second heater layer 4. The connecting portion 40 of the second heater layer 4 may be connected to the jumper layer 5 in such a manner that the distal end edge of the connecting portion 40 is overlaid on the outer peripheral edge of the jumper layer 5.

The joint portion 41 at which the connecting portion 40 of the second heater layer 4 and the jumper layer 5 are connected is liable to generate heat because a current concentrates at the joint portion 41 when the second heater layer 4 is energized. However, as in the example illustrated in FIG. 10A, resistance at the joint portion 41 is reduced by setting the thickness T3 of the joint portion 41 large. As a result, the amount of heat generated at the joint portion 41 when the second heater layer 4 is energized can be reduced. Thus, the formation of a localized hot spot can be suppressed. Accordingly, the thermal uniformity of the plate 2 can be further improved.

As illustrated in FIG. 10B, the connecting portion 40 of the second heater layer 4 may be connected to the jumper layer 5 such that the distal end edge of the connecting portion 40 is in contact with the outer peripheral edge of the jumper layer 5 in an abutting manner.

### (Description of Shaft)

Reference is made to FIG. 1. The shaft 10 is formed in a tubular shape with a first opening 11 and a second opening 12 which are a pair of openings positioned at both ends in an axial direction of the shaft 10. The shaft 10 supports the plate 2 on the second principal surface 23 (surface opposite to the first principal surface 22 by which the wafer is supported) side. A transverse cross section of the shaft 10 taken along a plane orthogonal to the axial direction has, for example, a circular shape, and the shaft 10 is arranged concentrically with the plate 2. A diameter of the shaft 10 is smaller than the diameter of the plate 2.

The shaft 10 may be formed from a sintered body made of the same ceramic material as the ceramic material for the plate 2, and may be formed from a sintered body made of a ceramic material different from the ceramic material for the plate 2.

A distal end portion 13 which is a portion surrounding the first opening 11 and a proximal end portion 14 which is a portion surrounding the second opening 12 of the shaft 10 can each be formed from, for example, a flange. The distal end portion 13 of the shaft 10 is bonded to the second principal surface 23 of the plate 2 by using, for example, diffusion bonding.

Various power feeding members 60, 70, and 90 and the thermocouple that measures the temperature of the plate 2 are housed in an internal space S of the shaft 10. As a result, the members made of metal, such as the power feeding members 60, 70, and 90 and the thermocouple, are isolated from the space inside the vacuum chamber of the semiconductor manufacturing apparatus, which is an external space, and are prevented from being exposed to plasma and the like.

### (Description of Actions and Effects of Ceramic Heater)

The ceramic heater 1 according to this embodiment described above has at least one slit 15 formed in each of the plurality of jumper layers 5. Each of the plurality of jumper layers 5 is divided into the plurality of regions 55 to 57 in plan view. The plurality of regions 55 to 57 include at least: the first region 55 on the innermost side, including the first end portion 53 to which a corresponding one of the second power feeding terminals 7 is connected; and the second region 56 on the outermost side, including the second end portion 54 to which a corresponding one of the connecting portions 40 is connected. The plurality of regions 55 to 57 are continuous in a zigzag pattern with the presence of the turn-back regions 58 and 59 therebetween in such a manner that the first region 55 extends in the positive circumferential direction of the plate 2 and the regions other than the first region 55 each extend in the circumferential direction opposite to the circumferential direction in which the region adjacent thereto on the inner side extends. In addition, the widths of the regions 55 to 57 of the jumper layers 5 are larger than the width of the second resistance heating element 42 which forms the second heater layer 4.

With the ceramic heater 1 according to this embodiment, with the features described above, in the plurality of jumper layers 5, when the second heater layer 4 is energized to achieve conduction between the second heater layer 4 and the second power feeding terminals 7, a current spreads in a wide area of the jumper layers 5. Thus, when the second heater layer 4 is energized, the jumper layers 5 generate heat uniformly in their entire or substantially entire areas. As a result, formation of a localized hot spot or cool spot in the plate 2 due to the heat generation of the jumper layers 5 themselves can be suppressed. In addition, the widths of the regions 55 to 57 of each of the jumper layers 5 are large and thus areas of the regions 55 to 57 are large. Accordingly, resistance in each of the regions 55 to 57 of the jumper layer 5 is reduced. As a result, the amount of heat generated in the jumper layers 5 when the second heater layer 4 is energized can be reduced. Thus, the thermal uniformity of the plate 2 can be improved.

In addition, in the ceramic heater 1 according to this embodiment, the widths of the regions 55 to 57 of the jumper layer 5 are 2 times or more and 75 times or less the width of the second resistance heating element 42 which forms the second heater layer 4. With the ceramic heater 1 according to this embodiment, this feature enables the resistance in each of the regions of the jumper layer to be suitably reduced. As a result, the amount of heat generated in the jumper layers when the second heater layer is energized can be reduced. Thus, the thermal uniformity of the plate can be further improved.

In addition, in the ceramic heater 1 according to this embodiment, the width of the slit is 1.0 mm or more. With the ceramic heater 1 according to this embodiment, this feature enables insulation to be ensured between the two regions on the opposite sides of the slit 15 in the jumper layer 5.

In addition, the ceramic heater 1 according to this embodiment includes one slit 15 formed in each of the plurality of jumper layers 5 in such a manner that the slit 15 divides the jumper layer 5 into two regions which are the first region 55 and the second region 56 in plan view. With the ceramic heater 1 according to this embodiment, this feature enables the widths of the regions 55 and 56 of each of the jumper layers 5 to be set large. As a result, the areas of the regions 55 and 56 of the jumper layer 5 can be increased to suitably reduce the resistance in each of the regions 55 and 56. Thus, the amount of heat generated in the jumper layers 5 when the second heater layer 4 is energized can be suitably reduced, and hence the thermal uniformity of the plate 2 can be further improved.

In addition, in the ceramic heater 1 according to this embodiment, each of the plurality of connecting portions 40 of the second heater layer 4 protrudes inward toward a corresponding one of the plurality of jumper layers 5 to be connected to the corresponding jumper layer 5. With the ceramic heater 1 according to this embodiment, this feature enables the second heater layer 4 and each of the jumper layers 5 to be connected to each other with a simple structure.

In addition, in the ceramic heater 1 according to this embodiment, the thickness of the joint portion 41 at which the connecting portion 40 and the jumper layer 5 are connected is larger than the thickness of the jumper layer 5 and the thickness of the second heater layer 4. With the ceramic heater 1 according to this embodiment, this feature enables resistance at the joint portion 41 to be reduced. As a result, the amount of heat generated at the joint portion 41 when the second heater layer 4 is energized can be reduced. Thus, the formation of a localized hot spot in the plate 2 can be suppressed, and hence the thermal uniformity of the plate 2 can be further improved.

In addition, in the ceramic heater 1 according to this embodiment, the thickness of the jumper layer 5 is larger than the thickness of the second heater layer 4. With the ceramic heater 1 according to this embodiment, this feature enables the resistance in the jumper layers 5 to be suitably reduced. As a result, the amount of heat generated in the jumper layers 5 when the second heater layer 4 is energized can be suitably reduced. Thus, the thermal uniformity of the plate 2 can be further improved.

In addition, in the ceramic heater 1 according to this embodiment, the central angle of the slit 15 is ½×360°/n (where “n” represents the number of jumper layers) or more. With the ceramic heater 1 according to this embodiment, this feature enables a current to spread in a wider area of the jumper layers 5 when the second heater layer 4 is energized. As a result, the thermal uniformity of the plate 2 can be further improved.

In addition, in the ceramic heater 1 according to this embodiment, the proportion of the area of the plurality of jumper layers 5 to the area of the inner zone 20 in plan view is 75% or more. With the ceramic heater 1 according to this embodiment, this feature enables the resistance in the jumper layers 5 to be suitably reduced. As a result, the amount of heat generated in the jumper layers 5 when the second heater layer 4 is energized can be suitably reduced. Thus, the thermal uniformity of the plate 2 can be further improved.

### Description of Modification Example

The description has been given above on the ceramic heater 1 according to one embodiment of the present disclosure. The embodiment can be modified in various ways without departing from the gist of the present disclosure. For example, the embodiment can be modified in manners described below. The modifications described below may be appropriately combined.

In the ceramic heater 1 according to the embodiment described above, the plurality of jumper layers 5 may be free of being arranged at the positions with the same height and may be arranged inside the plate 2 at positions with different heights in the thickness direction of the plate 2 so as to be built in the plate 2 in a state of being separated from each other.

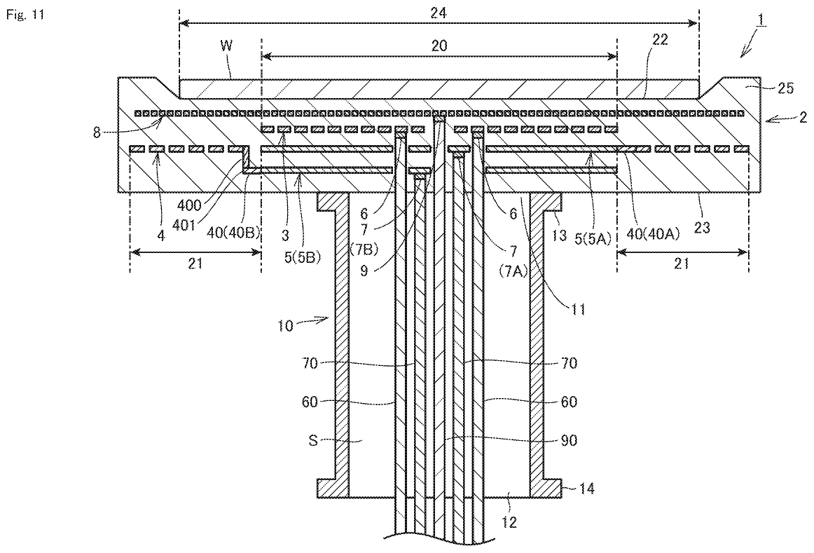

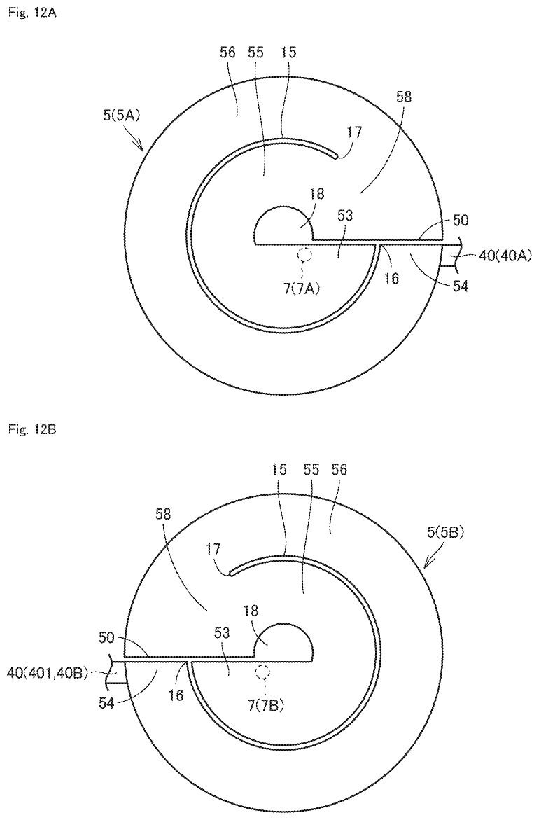

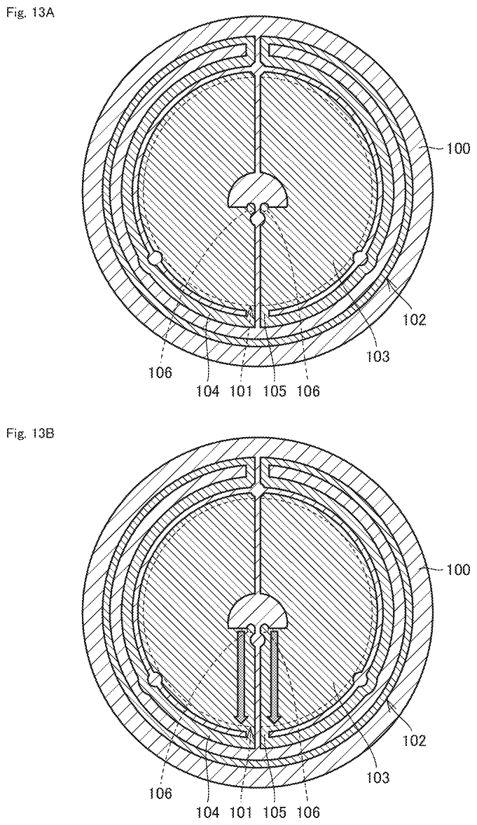

More specifically, as illustrated in FIG. 11 and FIGS. 12, for example, two jumper layers 5 which are the first jumper layer 5A and the second jumper layer 5B may be arranged as the plurality of jumper layers 5 inside the plate 2 at positions with different heights in the thickness direction of the plate 2 in a state of being separated from each other. In this modification example, the first jumper layer 5A is arranged at the position with the same height as the height at which the second heater layer 4 is arranged in the thickness direction of the plate 2, and the second jumper layer 5B is arranged below the first jumper layer 5A and the second heater layer 4.

Reference is made to FIG. 12A and FIG. 12B. The first jumper layer 5A and the second jumper layer 5B each have, for example, a circular or substantially circular shape in plan view, and are arranged concentrically with the plate 2. A single elongated cutout 50 extending from the outer peripheral edge to the center in plan view is formed in each of the first jumper layer 5A and the second jumper layer 5B. The first connecting portion 40A of the second heater layer 4 is electrically connected to the first jumper layer 5A at its outer peripheral edge in the vicinity of the cutout 50. The second connecting portion 40B of the second heater layer 4 is electrically connected to the second jumper layer 5B at its outer peripheral edge in the vicinity of the cutout 50.

Reference is made to FIG. 11. The second connecting portion 40B has an L-like bent shape in sectional view with a vertical portion 400 and a horizontal portion 401. The vertical portion 400 extends from the second heater layer 4 in the thickness direction of the plate 2. The horizontal portion 401 extends in a horizontal direction from a lower end of the vertical portion 400, and is connected to the second jumper layer 5B. Similarly to the example illustrated in FIG. 10A, it is preferred that a thickness of a joint portion at which the horizontal portion 401 of the second connecting portion 40B and the second jumper layer 5B are connected be larger than the thickness of the jumper layer 5 and the thickness of the second heater layer 4. The second connecting portion 40B is not required to have an L-like bent shape in sectional view. Conduction between the second connecting portion 40B and the second jumper layer 5B in a direction perpendicular thereto may be achieved using a conductive member extending in the thickness direction of the plate 2.

Reference is made to FIG. 12A and FIG. 12B. For example, one slit 15 is formed in each of the first jumper layer 5A and the second jumper layer 5B. A shape of the slit 15 in plan view is, for example, an arc-like shape. The slit 15 extends in an arc-like manner from the start end 16 to the terminal end 17 without reaching the cutout 50. In each of the first jumper layer 5A and the second jumper layer 5B, the start end 16 is in communication with the cutout 50, and is positioned on the outer side of the second power feeding terminal 7. The terminal end 17 is not in communication with the cutout 50. The terminal end 17 of the slit 15 is located at a position away from the cutout 50 in each of the first jumper layer 5A and the second jumper layer 5B. With the slit 15 described above, each of the first jumper layer 5A and the second jumper layer 5B includes the first region 55, the second region 56, and the first turn-back region 58. The first region 55 is located on the inner side of the slit 15, and extends in the positive circumferential direction of the plate 2 from the first end portion 53 to which a corresponding one of the second power feeding terminals 7 is connected. The second region 56 extends in the negative circumferential direction of the plate 2 to the second end portion 54 to which a corresponding one of the connecting portions 40 is connected. The first turn-back region 58 turns back from the first region 55 toward the second region 56.

Also in this modification example, in the first jumper layer 5A, a current that has been transmitted from the second power feeding terminal 7A being one of the second power feeding terminals 7 to the first jumper layer 5A flows from the first end portion 53 through the first region 55, turns back through the first turn-back region 58, then flows through the second region 56 to the second end portion 54, and is transmitted to the second heater layer 4 via the first connecting portion 40A. In the second jumper layer 5B, the current that has been transmitted from the second heater layer 4 via the second connecting portion 40B to the second jumper layer 5B flows through the second region 56 from the second end portion 54, turns back through the first turn-back region 58, then flows through the first region 55 to the first end portion 53, and is transmitted to the second power feeding terminal 7B being another one of the second power feeding terminals 7. As a result, when the second heater layer 4 is energized, the first jumper layer 5A and the second jumper layer 5B generate heat uniformly in their entire or substantially entire areas.

The central angle of the slit 15 is preferably 1800 or more and 300° or less, more preferably 2000 or more and 300° or less, still more preferably 2000 or more and 2800 or less, even more preferably 2400 or more and 2800 or less.

The number of slits 15 formed in each of the first jumper layer 5A and the second jumper layer 5B is not always limited to one, and two or more slits 15 may be formed therein as in the embodiment described above. However, it is preferred that one slit 15 or two slits 15 be formed.

In the ceramic heater 1 according to the embodiment described above, the shape of the slit 15 is not always required to be a smoothly curved shape like an arc-like shape in plan view, and may be an angularly curved shape.

It is to be understood that the embodiment disclosed herein is merely an example in all aspects and in no way intended to limit the present invention in any aspect. The scope of the present invention is defined by the appended claims and not by the above description, and it is intended that the present invention encompasses all modifications made within the scope and spirit equivalent to those of the appended claims.

1. A ceramic heater, comprising:
a plate including:
a first principal surface configured to support a wafer; and
a second principal surface positioned across a gap from the first principal surface in a thickness direction of the plate;
a first heater layer which is built in the plate, and which is formed from a resistance heating element configured to generate heat through energization;
a plurality of first power feeding terminals which are built in the plate so as to be arranged in a central portion of the plate when viewed in the thickness direction, and which are connected to the first heater layer;
a second heater layer having a ring shape which is built in the plate so as to be arranged on an outer side of the first heater layer when viewed in the thickness direction, and which is formed from a resistance heating element configured to generate heat through energization;
a plurality of second power feeding terminals which are built in the plate so as to be arranged in the central portion of the plate when viewed in the thickness direction, and which are configured to feed power to the second heater layer; and
a plurality of jumper layers which are built in the plate so as to be arranged on the second principal surface side with respect to the first heater layer in the thickness direction and arranged on an inner side of the second heater layer when viewed in the thickness direction,
wherein each of the plurality of jumper layers is connected to a corresponding one of the plurality of second power feeding terminals, and is connected to the second heater layer through intermediation of a corresponding one of a plurality of connecting portions provided to the second heater layer,
wherein the plurality of jumper layers each have at least one slit which divides the jumper layer into a plurality of regions, the plurality of regions including at least: a first region being an innermost region including a first end portion to which a corresponding one of the second power feeding terminals is connected; and a second region being an outermost region including a second end portion to which a corresponding one of the connecting portions is connected, when viewed in the thickness direction, the plurality of regions being continuous so that the first region extends in a positive circumferential direction and the region other than the first region extends in an opposite circumferential direction to a direction in which the region being adjacent on an inner side extends, and
wherein widths of the plurality of regions are larger than a width of the resistance heating element which forms the second heater layer.

2. The ceramic heater according to claim 1, wherein the widths of the plurality of regions are each 2 times or more and 75 times or less the width of the resistance heating element which forms the second heater layer.

3. The ceramic heater according to claim 1, wherein a width of the slit is 1.0 mm or more.

4. The ceramic heater according to claim 1, wherein the one slit is formed in each of the plurality of jumper layers, the slit dividing the jumper layer into, when viewed in the thickness direction, two regions including: the first region extending in the positive circumferential direction from the first end portion; and the second region extending to the second end portion in a negative circumferential direction being opposite to the positive circumferential direction.

5. The ceramic heater according to claim 1, wherein each of the plurality of connecting portions of the second heater layer protrudes inward toward a corresponding one of the plurality of jumper layers to be connected to the corresponding jumper layer.

6. The ceramic heater according to claim 5, wherein a thickness of a joint portion at which the connecting portion and the jumper layer are connected is larger than a thickness of each of the jumper layers and a thickness of the second heater layer.

7. The ceramic heater according to claim 1, wherein a thickness of each of the jumper layers is larger than a thickness of the second heater layer.

8. The ceramic heater according to claim 1,
wherein the plurality of jumper layers are arranged inside the plate at positions with the same height in the thickness direction, and are arranged in a state of being separated from each other in the circumferential direction when viewed in the thickness direction, and
wherein, when viewed in the thickness direction, an angle formed between a first line segment which connects a center of the plate and one end of the slit and a second line segment which connects the center of the plate and another end of the slit is ½×360°/n (where “n” represents the number of jumper layers) or more.

9. The ceramic heater according to claim 1,
wherein, when viewed in the thickness direction, the plate includes:
an inner zone which is a circular region within a first distance from a center of the plate, and in which the first heater layer and the plurality of jumper layers are arranged; and
an outer zone which is an annular region within a second distance from the center of the plate on an outer side of the inner zone, and in which the second heater layer is arranged, and
wherein a proportion of an area of the plurality of jumper layers to an area of the inner zone is 75% or more.
